(19) United States
(12) Patent Application Publication
(10) Pub. No.: US 2014/0151264 A1
(43) Pub. Date: Jun. 5, 2014

(54) WAFER CARRIER AND APPLICATIONS THEREOF

(71) Applicant: Tian-Sing HUANG, Tainan City (TW)

(72) Inventor: Tian-Sing HUANG, Tainan City (TW)

(21) Appl. No.: 14/094,915

(22) Filed: Dec. 3, 2013

(30) Foreign Application Priority Data
Dec. 4, 2012 (TW) 101145525

(51) Int. Cl. H01L 21/673

(52) U.S. Cl. CPC H01L 21/6732
USPC 206/711

(57) ABSTRACT

A wafer carrier includes a body, a door and a plurality of stages. The body has at least a sidewall and a wafer receiving cavity for receiving at least a wafer, wherein the wafer receiving cavity extends into the body from an opening formed on the sidewall. The door is disposed out of the opening. The stages are in contact with the sidewall for supporting the body, respectively.

### FIELD OF THE INVENTION

The invention relates to a wafer transport system, and more particularly to a wafer carrier and applications thereof.

### BACKGROUND OF THE INVENTION

In recent years, the performance requirements for a silicon wafer as a substrate are increasing along with obvious improvements in high integration and high performance of semiconductor elements. An epitaxial wafer is a wafer in which a silicon epitaxial layer is formed on a silicon base material by epitaxial growing. The epitaxial wafer has advantages such as less lattice defects, good properties and high stabilities, and can be used to manufacture wafers with large sizes (450 mm).

However, in a semiconductor manufacturing process such as a lithography process, an etching process, a cleaning process, an ion implantation process, thermal oxidation process, a thin film deposition process or a thin film removing processes etc., thermal or mechanical stresses are generally applied to the base material, which leads to a wafer warp problem. This will directly affect the yields in subsequent semiconductor manufacturing processes. In addition, this problem becomes worse with the trend of increased wafer size and reduced wafer thickness. Therefore, how the wafer warp problem in the manufacturing process can be ameliorated has become an issue to this industry.

### SUMMARY OF THE INVENTION

An aspect of the invention is to provide a wafer carrier including a body, a door and a plurality of stages. The body has at least a sidewall and a wafer receiving cavity extending into the body from an opening formed on the sidewall. The door is disposed out of the opening. The plurality of stages is in contact with the sidewall for supporting the body, respectively.

In an embodiment of the invention, the body has a first sidewall and a second sidewall, and the plurality of stages include a first stage in contact with the first sidewall; and a second stage in contact with the second sidewall, wherein the first stage and the second stage form a non-straight angle.

In an embodiment of the invention, the wafer carrier further comprises at least a wafer support member fixed on at least an interior wall of the wafer receiving cavity so that a wafer is substantially parallel to the first stage.

In an embodiment of the invention, the wafer carrier further comprises a plurality of handling flanges, wherein each of the handling flanges is disposed on one of the sidewalls.

In an embodiment of the invention, any two of the plurality of stages are parallel to each other.

Another aspect of the invention is to provide a wafer transport system including at least a wafer carrier and a conveying device disposed among a plurality of wafer processing machines for transferring the wafer carrier. In which, the wafer carrier includes a body, a door and a plurality of stages. The body has at least a sidewall and a wafer receiving cavity extending into the body from an opening formed on the sidewall. The door is disposed out of the opening. The plurality of stages is in contact with the sidewall for supporting the body, respectively.

In an embodiment of the invention, the body has a first sidewall and a second sidewall, and the plurality of stages include a first stage in contact with the first sidewall; and a second stage in contact with the second sidewall.

In an embodiment of the invention, the wafer carrier further comprises at least a wafer support member fixed on at least an interior wall of the wafer receiving cavity so that a wafer is substantially parallel to the first stage.

In an embodiment of the invention, the wafer carrier further includes a first handling flange disposed on the first sidewall and a second handling flange disposed on the second sidewall.

In an embodiment of the invention, the conveying device includes an overhead transport (OHT) vehicle for transferring the wafer carrier by linking with the first handling flange or the second handling flange.

In an embodiment of the invention, each of the wafer processing machines has a load port for receiving the first stage or the second stage.

In an embodiment of the invention, the wafer transport system further includes a buffer/stocker system disposed between adjacent two of the wafer processing machines, and joined with the conveying device.

In an embodiment of the invention, the buffer/stocker system includes a conveying port and an overturning device. The conveying port is used to receive the first stage; and the overturning device is used to overturn the wafer carrier such that the conveying port receives the second stage instead of the first stage.

In an embodiment of the invention, the overturning device is a robotic device.

A further aspect of the invention is to provide a wafer transport system including at least a wafer carrier and an OHT vehicle. The wafer carrier includes a body having a wafer receiving cavity, a door disposed out of the wafer receiving cavity and a stage for supporting the body. The OHT vehicle is used to overturn the wafer carrier during transferring the wafer carrier such that the stage forms a non-zero angle with a horizontal plane.

In an embodiment of the invention, the wafer carrier includes a handling flange for linking with the OHT vehicle.

A further another aspect of the invention is to provide a wafer buffer/stocker system including at least a wafer carrier, a conveying port, an overturning device and a stocker area. In which, the wafer carrier includes a body having a wafer receiving cavity, a door disposed out of the wafer receiving cavity and at least a stage for supporting the body. The conveying port is used to receive stage. The overturning device is used to overturn the wafer carrier such that the stage forms a non-zero angle with a horizontal plane. The stocker area is used to store the wafer carrier after it is overturned.

A further aspect of the invention is to provide a wafer transport method including the step of: using a wafer carrier to support at least a wafer, wherein the wafer carrier includes a body having a wafer receiving cavity; a door disposed out of the wafer receiving cavity; and a stage for supporting the body. Then, the step of using an overhead transport vehicle to transfer the wafer carrier among a plurality of wafer processing machines and perform an overturning step to the wafer carrier such that an active surface of the wafer form a non-zero angle with a horizontal plane is performed.

In an embodiment of the invention, each of the wafer processing machines has a load port for receiving the stage, and the overturning step is performed at the time the wafer carrier leaves or arrives at the load port

In an embodiment of the invention, the wafer transport method further includes the step of using a wafer the buffer/stocker system to store the wafer. The wafer the buffer/stocker system includes a conveying port, an overturning device and a stocker area. The conveying port is used to receive the stage. The overturning device is used to overturn the wafer carrier such that an active surface of the wafer forms a non-zero angle with a horizontal plane. The stocker area is used to store the wafer carrier after it is overturned.

According to the above, the invention provides a wafer carrier and a wafer transport system, which may optionally include a storage system of the wafer carrier. In which, the wafer carrier has at least a stage for supporting the body. In the wafer transport system, an angle formed between the stage and a horizontal plane can be a straight angle that is substantially 180° or a non-straight angle that is substantially smaller than 180° by changing or overturning the wafer carrier. In this way, the wafer in the system forms a straight angle that is substantially 180° or a non-straight angle that is substantially smaller than 180° with the horizontal plane. Thermal or mechanical stresses generated during the lithography process, the etching process, the cleaning process, the ion implantation process, thermal oxidation process, the thin film deposition process, the thin film removing process or other semiconductor manufacturing processes can be reduced by placing the wafer in different directions, changing a position of the gravity center of the wafer, or by the effect of gravity during storage and transferring of the wafer. In this way, the wafer warp problem can be ameliorated by a physical method. Therefore, the process yield can be improved without any additional process steps.

### BRIEF DESCRIPTION OF THE DRAWINGS

The invention will become more readily apparent to those ordinarily skilled in art after reviewing the following detailed description and accompanying drawings, in which:

FIG. 1 is a three-dimensional schematic diagram showing a wafer transport system according to an embodiment of the invention;

FIG. 2A is a three-dimensional schematic diagram showing a wafer carrier according to an embodiment of the invention;

FIG. 2B is a cross-sectional schematic diagram showing the wafer carrier along a line S1-S2 shown in FIG. 2A; and

FIG. 3 is a three-dimensional schematic diagram showing a wafer carrier according to another embodiment of the invention.

### DETAILED DESCRIPTION OF EMBODIMENTS

The invention provides a wafer carrier and applications thereof including a wafer transport system or a wafer storage system using the wafer carrier, which can ameliorate the wafer warp problem. In order to make the above and other objects, characteristics and advantages of the invention become more apparent, several wafer transport systems will now be described as preferred embodiments with reference to the drawings. It is to be noted that the following descriptions of the preferred embodiments of the invention are presented herein for purpose of illustration and description only. It is not intended to be exhaustive or to be limited to the precise form disclosed.

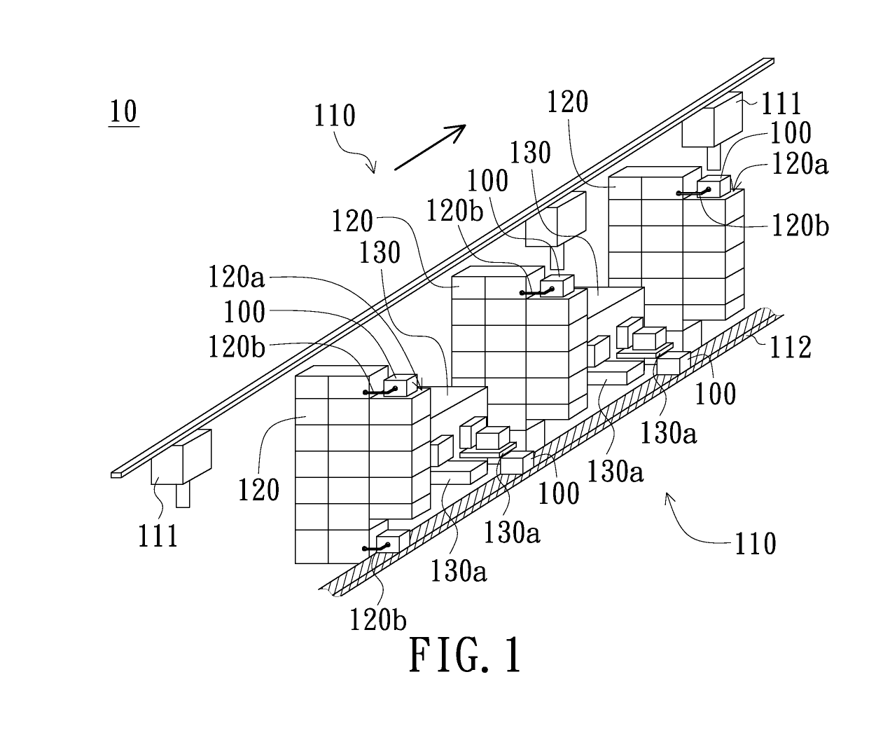

FIG. 1 is a three-dimensional schematic diagram showing a wafer transport system 10 according to an embodiment of the invention. Referring to FIG. 1, according to an embodiment of the invention, the wafer transport system 10 is disposed among a plurality of wafer processing machines 130 for transmitting a wafer 11 processed in an upstream manufacturing process to a downstream wafer processing machine 130 so as to perform a next manufacturing process. In this embodiment, the wafer transport system 10 includes at least a wafer carrier 100, a conveying device 110 and at least a buffer/stocker system 120.

The wafer carrier 100 has a wafer receiving cavity 105 for receiving a wafer 11 to be processed so as to ensure that a stable and clean environment is kept during the transportation of the wafer 11. A conveying device 110 is used to transfer the wafer carrier 100 among the wafer processing machines 130. The buffer/stocker system 120 is disposed between adjacent two wafer processing machines 130 and joined with the conveying device 110 for temporarily storing the wafer carrier 100.

In an embodiment of the invention, the wafer processing machines 130 may be working platforms for performing the same or different wafer manufacturing processes, for example, a lithography process, an etching process, a cleaning process, an ion implantation process, a thermal oxidation process, a thin film deposition process, a thin film removing process, a chemical mechanical polishing process, or a thin film epitaxial process. The conveying device 110 can be an overhead transport (OHT) vehicle 111 or a conveyer belt 112 that connects the wafer processing machines 130. The buffer/stocker system 120 is disposed between adjacent two working platforms as a transient stocker system for temporarily storing the wafer 11 to be processed (the wafer carrier 100). A wafer carrier 100 transferred from an upstream wafer processing machine 130 can be stored in the buffer/stocker system 120, standby for being scheduled, and then transferred a downstream wafer processing machine 130.

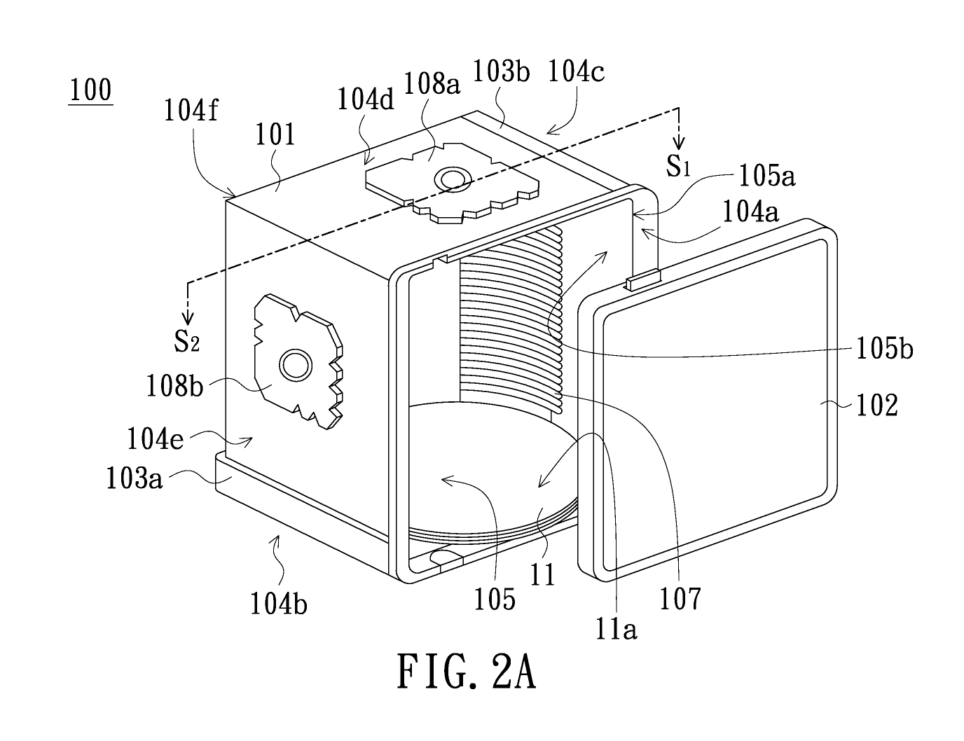

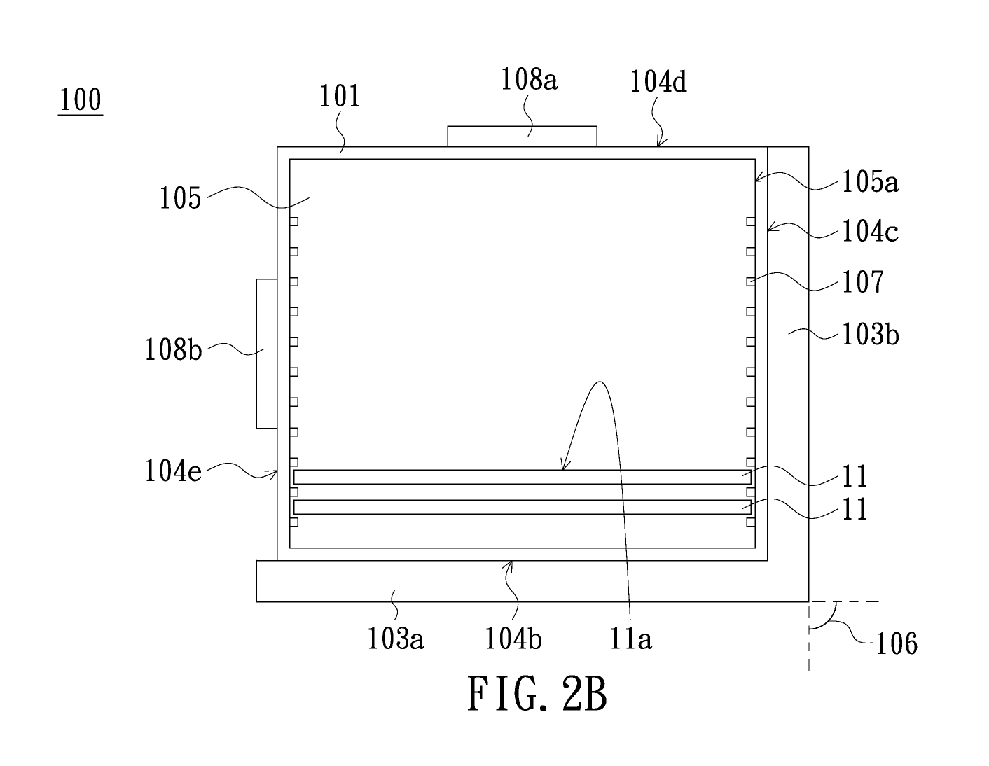

The wafer carrier 100 can be a structure of an independent box. For example, in an embodiment of the invention, the wafer carrier 100 can be a standard mechanical interface (SMIF) pod or a front opening unified pod (FOUP). Referring to FIGS. 2A and 2B, FIG. 2A is a three-dimensional schematic diagram showing a wafer carrier 100 according to an embodiment of the invention; and FIG. 2B is a cross-sectional schematic diagram showing the wafer carrier 100 along a line S1-S2 shown in FIG. 2A.

The wafer carrier 100 includes a body 101, a door 102, a plurality of stages and a plurality of handling flanges. The body 101 has at least a sidewall and a wafer receiving cavity 105. For example, in this embodiment, the body 101 is a rectangular shaped box having six sidewalls 104a, 104b, 104c, 104d, 104e and 104f. The wafer receiving cavity 105 extends into the body 101 from an opening 105a formed on the sidewall 104a, for accommodating at least a wafer 11. The door 102 is disposed out of the opening 105a and has an opening and closing function. During the transportation of the wafer 11, the opening 105a is closed such that the wafer receiving cavity 105 is in a sealed condition.

The plurality of stages are disposed on other sidewalls without the opening 105a. For example, in this embodiment, the wafer carrier 100 has two stages 103a and 103b, which are disposed on mutually perpendicular sidewalls 104b and 104c, respectively. Since both of the stages 103a and 103b are flat and directly adhered on the sidewalls 104b and 104c, bottom surfaces of the stages 103a and 103b form an angle 106 that is substantially 90°.

However, it is notable that the stages 103a and 103b can also be disposed on other sidewalls. For example, in other embodiments of the invention, the stages 103a and 103b can be disposed on mutually parallel sidewalls 104b and 104d, respectively. In this case, the bottom surfaces of the stages 103a and 103b will be parallel to each other. In some embodiments of the invention, if the opening 105a has a relatively reduced size, the stages may be disposed on the sidewall 104a formed with the opening 105a. In other embodiments of the invention, during transferring or storing the wafer 11, the door 102 can also be used as one of the stages of the wafer carrier 100. In addition, the stages 103a and 103b can also be non-flat. In some embodiments of the invention, the stages 103a and 103b can be constituted by a plurality of support members (not shown) formed on the sidewalls 104b and 104c. The stages 103a and 103b constituted by the support members form virtual planes (not shown), respectively, and the virtual planes of the stages 103a and 103b still form an angle that is substantially 90°.

In addition, the angle formed by the sidewalls 104b and 104c is not limited to a right angle. In another embodiment of the invention, two stages 103a and 103b respectively disposed on the sidewalls 104b and 104c form a non-straight angle that is substantially greater than or smaller than 90°.

The plurality of handling flanges are disposed on the sidewalls 104a, 104b, 104c, 104d, 104e and 104f. In this embodiment, the wafer carrier 100 has two sheet-like handling flange 108a and 108b disposed on the sidewalls 104d and 104e, respectively. The handling flange 108a and 108b is provided for linking with a gripper (not shown) of the OHT vehicle 111 or the conveyer belt 112 of the conveying device 110. The wafer carrier 100 can be transferred between two wafer processing machines 130 along with the movement of the OHT vehicle 111 or the conveyer belt 112. Since the sidewalls 104d and 104e are opposite to the sidewalls 104b and 104c disposed with the stages 103a and 103b, respectively, the handling flanges 108a and 108b are perpendicular to each other.

In addition, the wafer carrier 100 further includes at least a wafer support member 107 fixed on an interior wall 105b of the wafer receiving cavity 105. For example, in this embodiment, the wafer support member 107 has a shelf structure formed by a plurality of wafer teeth that are disposed on the interior wall 105b of the wafer receiving cavity 105. The wafer 11 can be placed on the wafer support member 107 such that the wafer 11 is substantially parallel to the stage 103a.

When the wafer carrier 100 is placed on a load port 130a of an upstream wafer processing machine 130 for performing a manufacturing process, the stage 103a is generally in contact with the load port 130a of the wafer processing machine 130 and is held horizontally. At this time, the wafer 11 in the wafer carrier 100 is also placed horizontally. When the wafer carrier 100 is going to leave the load port 130a of the wafer processing machine 130 after the manufacturing process is completed, the gripper of the OHT vehicle 111 or the conveyer belt 112 of the conveying device 110 can be selectively linked to the handling flange 108a or 108b. Then, the wafer carrier 100 will be taken away from the load port 130a of the wafer processing machine 130.

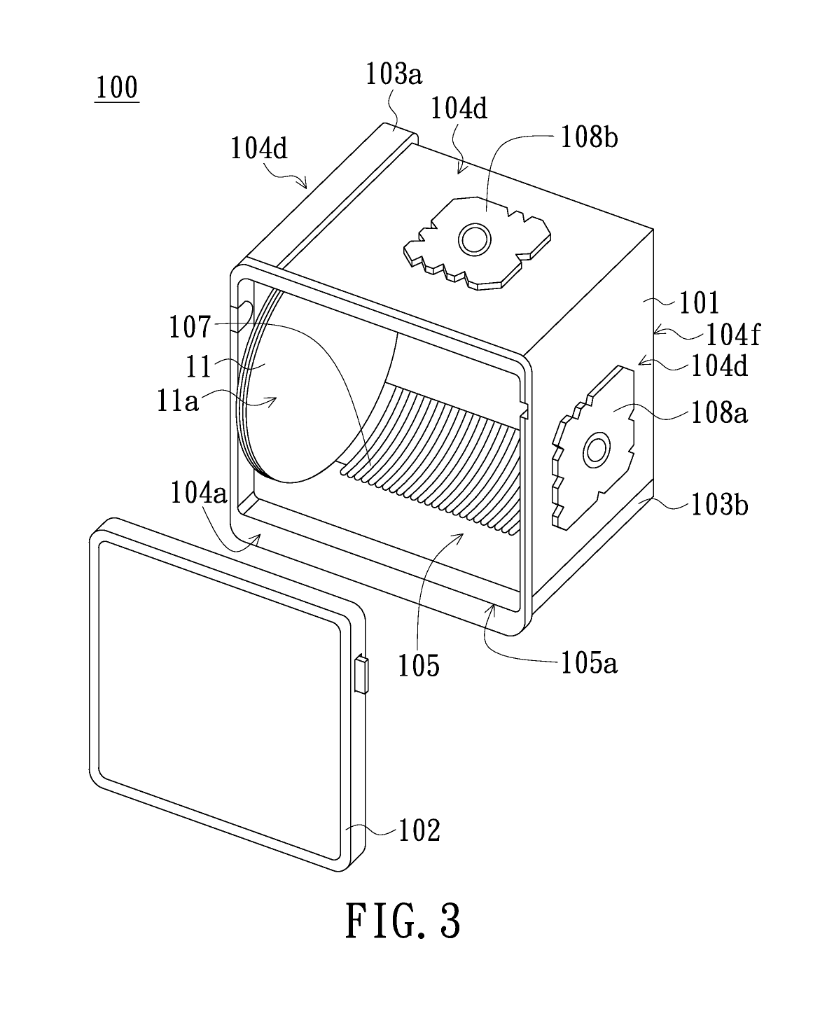

When the handling flange 108a is selected to be hung on the gripper of the OHT vehicle 111, since the handling flange 108a is disposed on the sidewall 104d right above the stage 103a, the stage 103a is held horizontally, and the wafer 11 in the wafer carrier 100 is still placed horizontally. On the other hand, when the handling flange 108b is selected to be hung on the gripper of the OHT vehicle 111, the wafer carrier 100 will be overturned at an angle (in this embodiment, 90°), and the wafer 11 will be placed at a non-straight angle (vertically) with respect to a horizontal plane during the transportation. That is, as shown in FIG. 3, an active surface 11a of the wafer 11 is perpendicular to a horizontal plane.

In an embodiment of the invention, when a handling flange is selected to be hung on the gripper of the OHT vehicle 111 such that the wafer carrier 100 is overturned at an angle of 180°, the active surface 11a of the wafer 11 that faces up and is parallel to a horizontal plane will also be overturned at 180° to face down and be parallel to the horizontal plane.

Similarly, the overturning step of the wafer carrier 100 can also be performed at the time that the wafer carrier 100 just arrives at the load port 130a of the next wafer processing machine 130. A position of the gravity center of the wafer 11 can be changed by placing the wafer 11 in different directions. In this way, thermal or mechanical stresses generated during the lithography process, the etching process, the cleaning process, the ion implantation process, thermal oxidation process, the thin film deposition process, the thin film removing process or other semiconductor manufacturing processes can be reduced and the wafer warp problem can be ameliorated by the effect of gravity.

In addition, the wafer carrier 100 can also be overturned in the buffer/stocker system 120 such that the wafer 11 forms a straight angle that is substantially 180° or a non-straight angle that is substantially smaller than 180° with a horizontal plane during the temporary storage period. In this way, thermal or mechanical stresses generated during the lithography process, the etching process, the cleaning process, the ion implantation process, thermal oxidation process, the thin film deposition process, the thin film removing process or other semiconductor manufacturing processes can be reduced and the wafer warp problem can be ameliorated by the effect of gravity.

For example, in this embodiment, the buffer/stocker system 120 includes a conveying port 120a and an overturning device 120b. The conveying port 120a is used to receive the wafer carrier 100 transferred from the OHT vehicle 111 or the conveyer belt 112 of the conveying device 110. The overturning device 120b is used to overturn the wafer carrier 100. As mentioned above, when the handling flange 108a is selected to be hung on the gripper of the OHT vehicle 111, the stage 103a reaches the conveying port 120a horizontally. Then, the wafer carrier 100 is received in the buffer/stocker system 120 after contacting the conveying port 120a of the buffer/stocker system 120. Next, the wafer carrier 100 is overturned by the overturning device 120b, which is preferably a robotic device, such that the stage 103b is contacted with the conveying port 120a. In this way, the wafer 11 is stored in a manner that it forms a non-straight angle (vertically) to a horizontal plane. Similarly, when the wafer carrier 100 is going to leave the buffer/stocker system 120, the wafer carrier 100 can be overturned again by the overturning device 120b, and then taken away from the buffer/stocker system 120 by the OHT vehicle 111. In this way, thermal or mechanical stresses generated during the lithography process, the etching process, the cleaning process, the ion implantation process, thermal oxidation process, the thin film deposition process, the thin film removing process or other semiconductor manufacturing processes can be reduced and the wafer warp problem can be ameliorated by the effect of gravity.

In addition, in an embodiment of the invention, the wafer carrier 100 may include only one stage (for example, the stage 103a) and one handling flange (for example, the handling flange 108a). In this case, the OHT vehicle 111 can perform the function of overturning the wafer carrier 100 without changing the handling flange. After the gripper of the OHT vehicle 111 is linked with the handling flange 108a, the wafer carrier 100 can be arbitrarily overturned by, but not limited to, a built-in robotic device of the OHT vehicle 111 during transferring of the wafer carrier 100. In this way, the stage 103a of the wafer carrier 100 forms a non-zero angle with the horizontal plane, thereby an active surface 11a of the wafer 11 forming a non-zero angle (for example, 90°) with the horizontal plane.

According to the above, the invention provides a wafer carrier and a wafer transport system, which may optionally include a storage system of the wafer carrier. In which, the wafer carrier has at least a stage for supporting the body. In the wafer transport system, an angle formed between the stage and a horizontal plane can be a straight angle that is substantially 180° or a non-straight angle that is substantially smaller than 180° by changing or overturning the wafer carrier. In this way, the wafer in the system forms a straight angle that is substantially 180° or a non-straight angle that is substantially smaller than 180° with the horizontal plane. A position of the gravity center of the wafer can be changed by placing the wafer in different directions. In this way, thermal or mechanical stresses generated during the lithography process, the etching process, the cleaning process, the ion implantation process, thermal oxidation process, the thin film deposition process, the thin film removing process or other semiconductor manufacturing processes can be reduced and the wafer warp problem can be ameliorated by the effect of gravity. Also, the process yield can be improved without any additional process steps.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wafer carrier, comprising:
a body having at least a sidewall and a wafer receiving cavity, wherein the wafer receiving cavity extends into the body from an opening formed on the sidewall;
a door disposed out of the opening; and
a plurality of stages in contact with the sidewall for supporting the body, respectively.

2. The wafer carrier as claimed in claim 1, wherein the body has a first sidewall and a second sidewall, and the stages comprises:
a first stage in contact with the first sidewall; and
a second stage in contact with the second sidewall, wherein the first stage and the second stage form a non-straight angle.

3. The wafer carrier as claimed in claim 2, further comprises at least a wafer support member fixed on at least an interior wall of the wafer receiving cavity so that a wafer is substantially parallel to the first stage.

4. The wafer carrier as claimed in claim 1, wherein any two of the stages are parallel to each other.

5. A wafer transport system, comprising:
at least a wafer carrier including:
a body having at least a sidewall and a wafer receiving cavity, wherein the wafer receiving cavity extends into the body from an opening formed on the sidewall;
a door disposed out of the opening; and
a plurality of stages in contact with the sidewall for supporting the body, respectively; and
a conveying device for transferring the wafer carrier among a plurality of wafer processing machines.

6. The wafer transport system as claimed in claim 5, wherein the body of the wafer carrier has a first sidewall and a second sidewall, and the stages comprises:
a first stage in contact with the first sidewall; and
a second stage in contact with the second sidewall, wherein the first stage and the second stage form a non-straight angle.

7. The wafer transport system as claimed in claim 6, the wafer carrier further comprises at least a wafer support member fixed on at least an interior wall of the wafer receiving cavity so that a wafer is substantially parallel to the first stage.

8. The wafer transport system as claimed in claim 7, wherein the body further has a third sidewall and a fourth sidewall, and the wafer carrier further comprises:
a first handling flange disposed on the third sidewall; and
a second handling flange disposed on the fourth sidewall.

9. The wafer transport system as claimed in claim 8, wherein the conveying device comprises an overhead transport vehicle for transferring the wafer carrier by linking with the first handling flange or the second handling flange.

10. The wafer transport system as claimed in claim 6, wherein each of the wafer processing machines has a load port for receiving the first stage or the second stage.

11. The wafer transport system as claimed in claim 6, further comprises a buffer/stocker system disposed between adjacent two of the wafer processing machines, and joined with the conveying device.

12. The wafer transport system as claimed in claim 11, wherein the buffer/stocker system comprises:
a conveying port for receiving the first stage; and
an overturning device for overturning the wafer carrier such that the conveying port receives the second stage instead of the first stage.

13. The wafer transport system as claimed in claim 12, wherein the overturning device is a robotic device.

14. The wafer transport system as claimed in claim 5, wherein any two of the stages are parallel to each other.

15. A wafer transport system, comprising:
at least a wafer carrier including:
a body having a wafer receiving cavity;
a door, is disposed out of the wafer receiving cavity; and
a stage, for supporting the body; and
an overhead transport vehicle for overturning the wafer carrier during transferring the wafer carrier such that the stage forms a non-zero angle with a horizontal plane.

16. The wafer transport system as claimed in claim 15, wherein the wafer carrier comprises a handling flange for linking with the overhead transport vehicle.

17. A wafer the buffer/stocker system comprising:
at least a wafer carrier including:
a body having a wafer receiving cavity;
a door disposed out of the wafer receiving cavity; and
at least a stage for supporting the body;
a conveying port for receiving the stage;
an overturning device for overturning the wafer carrier such that the stage forms a non-zero angle with a horizontal plane; and
a stocker area for storing the wafer carrier after it is overturned.

18. A wafer transport method comprising:
using a wafer carrier to support at least a wafer, wherein the wafer carrier includes:
a body having a wafer receiving cavity;
a door disposed out of the wafer receiving cavity; and
a stage for supporting the body;
using an overhead transport vehicle to transfer the wafer carrier among a plurality of wafer processing machines, and perform an overturning step to the wafer carrier such that an active surface of the wafer form a non-zero angle with a horizontal plane.

19. The wafer transport method as claimed in claim 18, wherein each of the wafer processing machines has a load port for receiving the stage, and the overturning step is performed at the time the wafer carrier leaves or arrives at the load port.

20. The wafer transport method as claimed in claim 18, further comprising using a wafer the buffer/stocker system to store the wafer, wherein the wafer the buffer/stocker system comprises:
a conveying port for receiving the stage;
an overturning device for overturning the wafer carrier such that an active surface of the wafer form a non-zero angle with a horizontal plane; and
a stocker area for storing the wafer carrier after it is overturned.
